(19) United States
(12) Patent Application Publication
(10) Pub. No.: US 2008/0099438 A1
(43) Pub. Date: May 1, 2008

(54) Wavefront modulation methods for EUV maskless lithography

(76) Inventor: Yijian Chen, Albany, CA (US)

Correspondence Address: Yijian Chen, 1049 Talbot Avenue, Albany, CA, 94706, US

(21) Appl. No.: 11/590,479

(22) Filed: Nov. 1, 2006

(51) Int. Cl. C23F 1/00; G03F 1/00

(52) U.S. Cl. 216/67; 216/41; 430/4; 430/5

(57) ABSTRACT

Wavefront modulation methods based on a general multiple-scan imaging model are invented for EUV maskless lithography. The model includes the effects of both deterministic image blur caused by uniform linear scanning of the wafer and stochastic blur due to laser's random timing jitter. It is shown that the expected blurred image intensity is a linear function of a “double convolution” of the stationary image with the “scanning pupil” function and the probability density function of the laser's timing jitter. Consequently, the spectrum of the expected blurred image is the product of the stationary image spectrum and the spectrums of the “scanning pupil” function and the probability density function. An inverse-filtering method to modulate EUV wavefront is invented to reduce image blur by coating the EUV reflective mirror on the Fourier plane with a thin absorbing layer whose thickness profile will determine the amplitude and phase modulation of the incident wave. It is also proposed that the random image noise can be minimized with a Wiener-type filter and the placement errors can be reduced by increasing the scan times. Two processes are invented to fabricate the proposed filters.

### 1. BACKGROUND OF THE INVENTION

Micromirror-based EUV (extreme ultraviolet, 13.5 nm) maskless lithography recently has been proposed as a potential candidate for the next-generation lithography technology owing to its low cost of ownership, defect tolerance, design flexibility, and affordable phase-shift and double-exposure capabilities [1-2]. Another advantage of its significantly improved process window is nevertheless seldom discussed. EUV DOF (depth of focus) is very small and further increase of NA (to improve the resolution) will degrade it more. Even EUV mask-based resolution enhancement techniques such as phase-shift mask have been widely researched, its application in low-to-medium-volume production will simply push the already high cost of lithographic ownership to a prohibitive level. However, if we apply the phase-shift and DOF-enhancement (e.g., multiple exposure with varying focus levels and micromirror phase configurations ) functions built in maskless lithography to improve EUV resolution without raising up NA, the process window can be controlled at a level within our manufacturing capability [3, 4].

On the other hand, it has been demonstrated that the scanning speed (and throughput) of EUV maskless lithography is limited by the effect of image blur for two mechanisms [2]. First, the pattern on the micromirror array remains stationary while the wafer is moving during the exposure process. This will blur the image and cause systematic (correctable) shift of the image position even in a one-scan exposure. Secondly, the random timing jitter of the laser pulses during a multiple-scan exposure can result in further stochastic image blur and placement errors as well. It is therefore important to consider both deterministic and stochastic blur effects (due to wafer scanning and laser's random timing jitter, respectively), and search for a solution that will address both issues.

### 2. BRIEF SUMMARY OF THE INVENTION

In this patent, we first show that the blurred image is a “double convolution” of the stationary (unblurred) image intensity with the “scanning pupil” function (to be defined later) and the probability density function of the laser's timing jitter. According to the convolution theorem, the Fourier transfer (spectrum) of the final blurred image is just the product of the stationary image spectrum and the spectrums of the “scanning pupil” function and the probability density function. Based on above analysis, several reflective wavefront modulation methods are invented as EUV lithography uses reflective optics. The fundamental idea is coating one EUV mirror (located on the Fourier plane) with a thin absorbing layer whose thickness profile will determine the amplitude modulation of the incident EUV wave. There are many materials that can be used for the absorbing layer such as SiO₂, Si, Ru, just to name a few. The thickness profile can be calculated based on the required modulation profile and the absorption coefficient. Phase modulation can be independently introduced by etching certain profile into the EUV mirror before depositing the absorbing layer. Adding one more EUV reflective mirror will sacrifice certain amount of photon energy due to its partial absorption of EUV light. However, this does not seem to be a serious throughput bottle-neck issue since the entry-level EUV maskless tool will be for low-to-medium-volume manufacturing, and the available EUV source power should be enough for us to use one extra wavefront-modulation mirror to increase the throughput by faster scanning. Moreover, it is proposed that the random image blur due to laser's timing jitter can be minimized with a Wiener Filter and the placement error can be reduced by increasing the scan times.

### 3. DETAILED DESCRIPTION OF THE INVENTION

We shall first show a general multiple-scan imaging model to include the stochastic blur effect caused by the laser's random timing jitter. Since pulsed EUV light source operates up to ˜10 kHz (repetition rate) with a 5-15 ns pulse duration, it necessitates using a “flash” architecture wherein the pattern on micromirror array is set-up before each pulse of light. Even the array is stationary during the exposure process, the patterns electrically generated on the micromirror array vary both spatially and temporally. Ideally the laser pulses will flash at a perfect repitition rate, and the patterns on the array are electrically refreshed by the real-time data input based on the assumption of a constant repetition rate of laser pulses. Even the wafer is scanned at a uniform speed, the patterns on the array vary accordingly such that ideally the same location on the wafer will be printed with the same pattern for several times without any misalignment. However, due to the timing jitter of laser pulses (which is equivalent to the noise in the repetition rate of laser pulses), the pattern printed during each individual pulse does not align perfectly with those patterns printed during other pulses. The final image produced in the resist is the sum of all individual images printed by corresponding laser pulses; therefore, the misalignment effect will appear as a blurred final image. Assume the wafer is scanned/exposed n times at a uniform speed-V in X direction, and the stationary/unblurred image corresponding to each scanning is the same: f (x, y). Due to the wafer scanning, each individual image will suffer from a deterministic blur effect. Ideally all n images will overlap perfectly with each other and no further blur can be observed. However, due to the timing jitter of EUV laser pulses, all the individual images will have random placement errors. Consequently, the final image as the sum of all individual image profiles will be further blurred. Without loss of generality, we shall ignore y dependence and focus on the 1-D case which can be readily extended to the 2-D analysis. Given a rectangle-function laser pulse lasting for a period of T and the time delay of the ith pulse as τᵢ (relative to the perfect timing determined by the repetition rate/frequency of the laser pulses, see FIG. 1), the deterministic blurred image due to wafer scanning is:

$${I}_{i} ( x , {τ}_{i} ) = \frac{1}{T} {\int }_{{τ}_{i}}^{T + {τ}_{i}} f ( x - V \cdot t ) d t \qquad ( 1 )$$

Here we have not considered the stochastic blur effect yet since above formula is only for one scan/exposure. Set: μ=Vt, equation (1) can be written as:

$${I}_{i} ( x , {τ}_{i} ) = \frac{1}{VT} {\int }_{V {τ}_{i}}^{V ( T + {τ}_{i} )} f ( x - μ ) d μ \qquad ( 2 )$$

We define a “scanning pupil” function as below:

$${p}_{s} ( μ , {τ}_{i} ) = \{ \begin{matrix}1 / VT ( V {τ}_{i} < μ < V {τ}_{i} + VT ) \\ 0 ( μ < V {τ}_{i} , μ > V {τ}_{i} + VT )\end{matrix} \qquad ( 3 )$$

### Equation (3) can be expressed as a convolution (symbol represents the convolution):

$${I}_{i} ( x , {τ}_{i} ) = {\int }_{- ∞}^{+ ∞} f ( x - μ ) \cdot {p}_{s} ( μ , {τ}_{i} ) d μ = f ⊗ {p}_{s} \qquad ( 4 )$$

### The final image is the sum of all the individual images, i.e.,

$${I}_{t} ( x ) = {\sum }_{i = 1}^{n} {I}_{i} ( x , {τ}_{i} )$$

wherein the time delay τᵢ is a random variable described by a probability density function q(τᵢ) that can be experimentally characterized. The expected total image intensity is:

$${\overline{I}}_{t} ( x ) = E [ {\sum }_{i = 1}^{n} {I}_{i} ( x , {τ}_{i} ) ] = {\sum }_{i = 1}^{n} E [ {I}_{i} ( x , {τ}_{i} ) ] = nE [ {I}_{i} ( x , {τ}_{i} ) ] \qquad$$

Here, the symbol E represents the statistical average or expected value and we have assumed that each individual image has the same expected profile. It should be kept in mind that each time delay τᵢ will simply shift the position of the corresponding individual image without changing its shape. In other words, each individual image is a space-invariant function: Iᵢ(x, τᵢ)=Iᵢ(x−V·τᵢ). Thus we can rewrite the expected total intensity as:

$${\overline{I}}_{t} ( x ) = nE [ {I}_{i} ( x , {τ}_{i} ) ] = n {\int }_{- ∞}^{+ ∞} {I}_{i} ( x - V \cdot {τ}_{i} ) q ( {τ}_{i} ) d {τ}_{i} = n {\int }_{- ∞}^{+ ∞} {I}_{i} ( x - V \cdot τ ) q ( τ ) d τ \qquad ( 5 )$$

Set: z=V·τ, then above equation becomes:

$${\overline{I}}_{t} ( x ) = n {\int }_{- ∞}^{+ ∞} {I}_{i} ( x - z ) {q}_{z} ( z ) d z = {nI}_{i 0} ⊗ {q}_{z} \qquad ( 6 )$$

where we define: Iᵢ₀=Iᵢ(x,τ=0)=Iᵢ(x), q_{z}(z)=q(z/V)/V. Combining equation (4) and (6) yields:

Īₜ(x)=n·f [symbol] pₛ₀ [symbol] q_{z} (7)

### According to the convolution theorem, we obtain an important relation in the spectrum domain fₓ:

Īₜ^{F}(fₓ)=n·F(fₓ)Pₛ₀(fₓ)Q_{z}(fₓ) (8)

Here, Īₜ^{F}(fₓ),F(fₓ),Pₛ₀(fₓ),Q_{z}(fₓ) are the Fourier transform of Īₜ, f, pₛ₀, q_{z} respectively. The subscript “0” in pₛ₀ and Pₛ₀ represents the zero-delay scanning pupil function (τ=0) defined by (3). Moreover, it is valuable to study the influence of scan times n on the variance of the resist image's position shift. Normally resist CD is measured at the threshold intensity (e.g., 30% of the open-field intensity) of the final image profile. To avoid the difficulty of numerically finding the threshold value of the total intensity in a multiple-scan exposure while still being able to gain the physical insight of its statistical characteristics, we approximate the shift of the final image (or resist position) by the average of all the individual images' shift:

$${\sum }_{i = 1}^{n} ( V {τ}_{i} ) / n .$$

Therefore, the variance of the resist position's shift is given as:

$${σ}^{2} [ {\sum }_{i = 1}^{n} ( V {τ}_{i} ) / n ] = \frac{1}{{n}^{2}} {σ}^{2} [ {\sum }_{i = 1}^{n} V {τ}_{i} ] = \frac{1}{n} {σ}^{2} [ V {τ}_{i} ] \qquad ( 9 )$$

### It is evident that the variance of n-scan random displacement is significantly reduced by a factor of n from the one-scan case.

An “inverse” filter on the Fourier plane of the image is invented and defined as:

$$M ( {f}_{x} ) = \frac{1}{{P}_{s 0} ( {f}_{x} ) \cdot {Q}_{z} ( {f}_{x} )} \qquad ( 10 )$$

It will restore the original image by eliminating both deterministic blur (caused by wafer scanning) and the statistically-averaged blur (caused by the probability density function of the timing jitter) in the spectrum domain. M(fₓ) when normalized by its maximum value is equivalent to reflection ratio of incident light intensity if no phase modulation is involved. Therefore, such modulation function can be achieved by introducing an absorbing plate (filter) on the Fourier plane.

In this patent, we invent two processes that can be applied to fabricate this filter. The first process is shown in FIG. 3. An absorbing layer is deposited on a multi-layer EUV mirror in step (1). A standard lithographic process is used to print a feature followed by a plasma etching to transfer that feature into the absorbing layer as shown in step (2). Similar process is repeated to produce a multiple-step profile as shown in steps (3), (4), and (5). We only show three “steps” in the figure, but this process is able to produce more “steps” which will mimic the continuous profile required by the modulation function. The deposition thickness of the absorbing layer must be controlled accurately to obtain the desired reflection ratio.

The second process is shown in FIG. 4 wherein a thick absorbing layer is deposited on a multi-layer EUV mirror in step (1) first. A standard lithographic process is used to print a feature followed by a plasma etching to transfer that feature into the absorbing layer as shown in step (2). Unlike the first process, no extra absorbing layer needs to be deposited. The lithographic and etching processes are repeated to produce a multiple-step profile as shown in step (3). Again, we only show three “steps” in the figure, but this process is able to produce more “steps” which will mimic the continuous profile required by the modulation function. The etched thickness of the absorbing layer must be controlled accurately to obtain the desired reflection ratio.

In general, if there are other random processes that bring noise to the pre-filtered image, the restored image spectrum G(fₓ) can be described by introducing a noise nₜ^{F}(fₓ) term as:

$$G ( {f}_{x} ) = [ {I}_{t}^{F} ( {f}_{x} ) + {n}_{t}^{F} ( {f}_{x} ) ] \cdot M ( {f}_{x} ) = n F ( {f}_{x} ) + \frac{{n}_{t}^{F} ( {f}_{x} )}{{P}_{s 0} ( {f}_{x} ) \cdot {Q}_{z} ( {f}_{x} )} \qquad ( 11 )$$

In above derivation, equation (8) has been used. We can see from equation (11) that the inverse filtering will suffer from the ill-defined singularity problem if the spectrum of either zero-delay scanning pupil function or the probability density function has zero points within the spectral window of interest. To simplify our analysis, we assume that the laser pulse length T is much longer than the characteristic length of time delay distribution. Consequently, the smallest amplitude of the spectral value |fₓ₀|, at which Q_{z}(fₓ₀) is equal to zero, will be larger than those of Pₛ₀(fₓ). For the lithographic application, we focus our attention on the optical spectrum window limited by ±NA/λ·2 (NA is the numerical aperture of the optical system and λ is the wavelength of EUV light) and only consider the zero points of Pₛ₀(fₓ). Since pₛ₀(μ) is a rectangle function, its spectrum is simply a Sinc function whose inverse amplifies the higher-order wave components while suppresses the zero-order DC component. The zero points of Pₛ₀(fₓ) are at fₓ=±1/VT, ±2/VT, . . . and as we mentioned before, 1/VT must be larger than the maximum frequency 2NA/λ to avoid the singularity problem. Normally, the scanning distance VT is smaller than the feature size k₁ λ/NA (k₁<1) thus this requirement is satisfied. The relation between spatial frequency fₓ and incident angle of light θ (relative to the optical axis), fₓ=sin θ/λ, can be applied to calculate the modulation profile as a function of sin θ. Moreover, the general noise effect as described by equation (11) can be minimized with an optimal filter such as Wiener-type filter [5]:

$${M}_{t} ( {f}_{x} ) = \frac{{M}^{*} ( {f}_{x} )}{{\vert M ( {f}_{x} ) \vert}^{2} + {Φ}_{n} ( {f}_{x} ) / {Φ}_{0} ( {f}_{x} )}$$

where * denotes complex conjugate, Φₙ(fₓ) and Φ₀(fₓ) represent the power spectral densities of the noise and original image.

### 4. BRIEF DESCRIPTION OF THE FIGURES

FIG. 1. depicts a series of n ideal rectangle EUV laser pulses (bottom) and more practical jittering (top) pulses that will print the same spot on the wafer during an n-scan exposure.

FIG. 2. depicts a reflective EUV filter on the Fourier plane with amplitude modulation. The continuous profile of the absorbing layer is mimicked by a multiple-step profile. Thicker absorbing layer reflects less EUV light as shown in the figure. Phase modulation can be independently controlled by etching into EUV multilayer mirror with varying depth (not shown in the figure).

FIG. 3. depicts one process to fabricate an EUV amplitude-modulation filter.

FIG. 4. depicts another process to fabricate an EUV amplitude-modulation filter.

### REFERENCES

[1] Y. Chen, C. Chu, J.-S. Wang, Y. Shroff, W. G. Oldham, “Design and fabrication of tilting and piston micromirrors for maskless lithography,” Proc. of SPIE, Vol. 5751, pp. 1023-1037, 2005.
[2] Y. Chen, Y. Shroff, “The effects of wafer-scan induced image blur on CD control, image slope, and process window in maskless lithography,” Proc. of SPIE, Vol. 6151, 61512D, 2006.
[3] J.-S. Wang, “High-resolution optical maskless lithography based on micromirror arrays,” PhD Thesis, Department of Electrical Engineering, Stanford University, March, 2006.
[4] A. K.-K. Wong, “Resolution Enhancement Techniques in Optical Lithography,” SPIE Press, Bellingham, p. 175, 2001.
[5] J. W. Goodman, “Introduction to Fourier Optics,” McGraw-Hill, 1996.

A number of wavefront modulation methods are invented to reduce both the deterministic and stochastic blur effects in EUV maskless lithography. The wafer scanning speed (and throughput) of EUV maskless lithography is limited by the effect of image blur for two mechanisms. First, the pattern on the micromirror array remains stationary while the wafer is moving during the exposure process. This will blur the image and cause systematic (correctable) shift of the image position. Secondly, the random timing jitter of the laser pulses during a multiple-scan exposure can result in further stochastic image blur and placement errors as well.

In the attached detailed description of this patent, we show that the blurred image is a “double convolution” of the stationary (unblurred) image intensity with the “scanning pupil” function (to be defined later) and the probability density function of the laser's timing jitter. According to the convolution theorem, the Fourier transfer (spectrum) of the final blurred image is just the product of the stationary image spectrum and the spectrums of the “scanning pupil” function and the probability density function.

1. Based on above analysis, a reflective wavefront modulation method is invented as EUV lithography uses reflective optics; the fundamental idea is coating one EUV mirror (located on the Fourier plane) with a thin absorbing layer whose thickness profile will determine the amplitude modulation of the incident EUV wave.

2. There are many materials that can be used for the absorbing layer such as SiO₂, Si, Ru, just to name a few and not limited to them, and the thickness profile can be calculated based on the required amplitude modulation (reflection) and the absorption coefficient.

3. A 1-D wavefront modulation function on the Fourier plane (spectrum plane) of the image is invented and defined as:
$$M ( {f}_{x} ) = \frac{1}{{P}_{s 0} ( {f}_{x} ) \cdot {Q}_{z} ( {f}_{x} )}$$
, which will restore the original image by eliminating both deterministic blur (caused by wafer scanning) and the statistically-averaged blur (caused by the probability density function of the timing jitter) in the spectrum domain (details about this function shown in the attached description of the patent).

4. The zero points of Pₛ₀(fₓ) are at fₓ=±1/VT,±2/VT, . . . , wherein 1/VT must be larger than the maximum frequency 2NA/λ to avoid the singularity problem of the modulation function defined in claim 3, wherein-V is wafer scanning speed, T is laser pulse length, NA is the numerical aperture of the optical system, and λ is EUV wavelength.

5. The relation between fₓ and the light incident angle θ (relative to the optical axis), fₓ=sin θ/λ, can be substituted into the modulation function defined in claims 3 and 9 to calculate the modulation profile as a function of sin O .

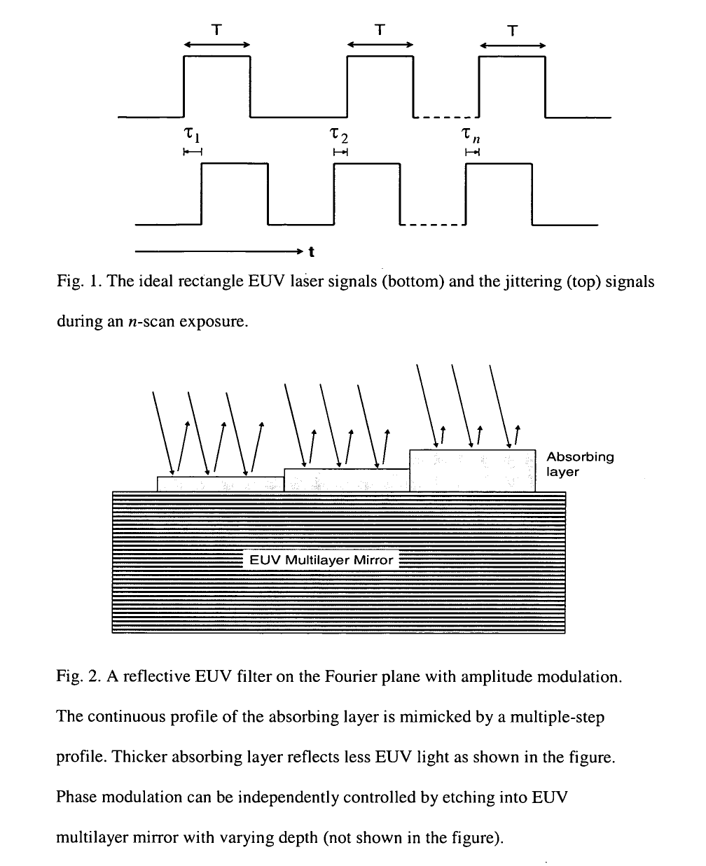

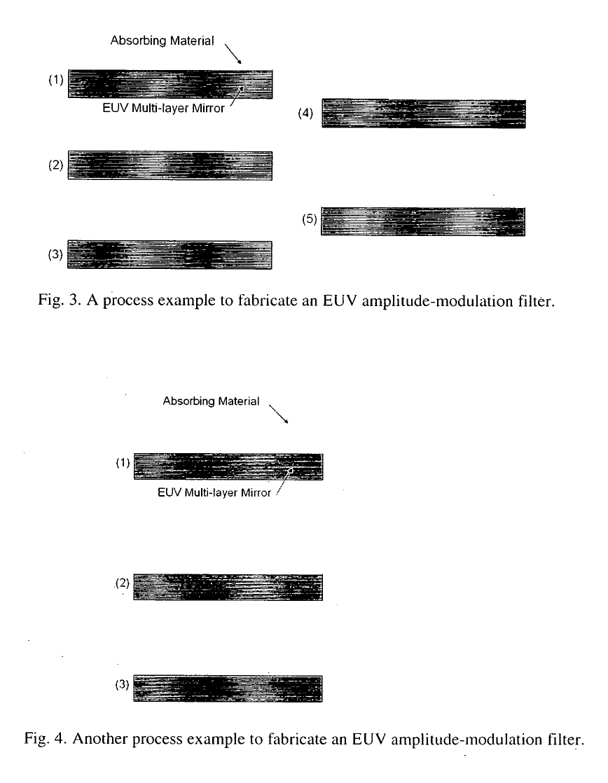

6. A process as shown in FIG. 1 is invented to fabricate the filter, the process sequence comprising:
a. An absorbing layer deposited on a multi-layer EUV mirror in step (1).
b. A standard lithographic process used to print a feature, followed by a plasma etching to transfer that feature into the absorbing layer as shown in step (2).
c. Similar process repeated to produce a multiple-step profile as shown in steps (3), (4), and (5). We only show three “steps” in the figure, but this process is able to produce more “steps” which will mimic the continuous profile required by the modulation function.
d. The deposition thickness of the absorbing layer must be controlled accurately to obtain the desired reflection ratio.

7. The second process as shown in FIG. 2 is invented to fabricate the filter, the process sequence comprising:
a. A thick absorbing layer is deposited on a multi-layer EUV mirror in step (1) first.
b. A standard lithographic process is used to print a feature followed by a plasma etching to transfer that feature into the absorbing layer as shown in step (2).
c. Unlike the first process, no extra absorbing layer needs to be deposited. The lithographic and etching processes are repeated to produce a multiple-step profile as shown in step (3). Again, we only show three “steps” in the figure, but this process is able to produce more “steps” which will mimic the continuous profile required by the modulation function.
d. The etched thickness of the absorbing layer must be controlled accurately to obtain the desired reflection ratio.

8. Phase modulation can be independently introduced by etching certain profile into the EUV mirror before depositing the absorbing layer.

9. The random image blur due to laser's timing jitter can be minimized with a Wiener Filter defined as:
$${M}_{t} ( {f}_{x} ) = \frac{{M}^{*} ( {f}_{x} )}{{\vert M ( {f}_{x} ) \vert}^{2} + {Φ}_{n} ( {f}_{x} ) / {Φ}_{0} ( {f}_{x} )}$$
where * denotes complex conjugate, Φₙ(fₓ) and Φ₀(fₓ) represent the power spectral densities of the noise and original image. This filter requires the capability of phase modulation of EUV incident wave, which can be achieved by the method of claim 8.

10. The placement error can be reduced by increasing the scan times n.
